(19) United States
(12) Patent Application Publication
(10) Pub. No.: US 2026/0372015 A1
(43) Pub. Date: Nov. 19, 2026

(54) METHOD FOR PROCESSING PLATE-SHAPED OBJECT, METHOD FOR MANUFACTURING SEMICONDUCTOR DEVICE CHIP, AND PROCESSING APPARATUS

(71) Applicant: DISCO CORPORATION, Tokyo (JP)

(72) Inventor: Norifumi HODOHARA, Tokyo (JP)

(21) Appl. No.: 19/645,504

(22) Filed: Apr. 13, 2026

(30) Foreign Application Priority Data
May 13, 2025 (JP) 2025-080566

(51) Int. Cl. H10P 74/20; B24B 37/005; B24B 37/04; B24B 37/27; B24B 49/04; H10P 52/20; H10P 72/00; H10P 72/76; H10P 72/78; H10P 74/00

(52) U.S. Cl. CPC H10P 74/203; B24B 37/005; B24B 37/042; B24B 37/27; B24B 49/04; H10P 52/202; H10P 72/0428; H10P 72/7604; H10P 72/78; H10P 74/238

(57) ABSTRACT

A method for processing a plate-shaped object having a chamfered portion includes a preliminary processing step, a measurement step, and a main processing step. The preliminary processing step includes performing at least one of processing the chamfered portion by a distance smaller than a target predetermined distance or processing the chamfered portion by a depth shallower than a target predetermined depth. The measurement step includes measuring at least one of a distance from the outer peripheral edge or a depth from the front surface of a region processed at the preliminary processing step. The main processing step includes performing at least one of processing the plate-shaped object up to the target predetermined distance or processing the plate-shaped object up to the target predetermined depth, based on at least one of the distance or the depth measured at the measurement step.

### CROSS-REFERENCE TO RELATED APPLICATIONS

The present application claims priority to and incorporates by reference the entire contents of Japanese Patent Application No. 2025-080566 filed in Japan on May 13, 2025.

### TECHNICAL FIELD

The present disclosure relates to a method for processing a plate-shaped object, a method for manufacturing a semiconductor device chip, and a processing apparatus.

### BACKGROUND

Some plate-shaped objects such as wafers have chamfers formed from the front surface to the back surface at their outer peripheral edges. When such a plate-shaped object is thinned to a half thickness or less, what is called a sharp edge may be formed at the outer periphery, and the plate-shaped object may be damaged.

To prevent this, there is known a technique in which a cutting blade is used to trim the outer periphery of the plate-shaped object and remove the chamfer, and then thinning is performed (see, for example, JP 2000-173961 A).

The cutting blade of a processing apparatus mentioned above undergoes wear, damage, etc. in the course of cutting; thus, the cutting blade is replaced with a new cutting blade as necessary. When replacement with a new cutting blade is made, it is necessary to check whether the width and depth of a stepped portion formed in a chamfered portion by the new cutting blade fall within predetermined permissible ranges.

Thus, it is necessary to cut into a silicon piece held on a sub-chuck table to measure the width and depth of the groove and make corrections.

For this reason, the method described in JP 2000-173961 A has a problem of poor productivity because the processing of forming a stepped portion using the processing apparatus cannot be performed until the inspection to confirm whether the stepped portion has been properly formed by trimming is completed.

Errors in the width of the stepped portion formed by trimming cause problems such as reduction in the number of chips yielded (effective area) and the inability to completely remove the chamfered portion (resulting in a sharp edge after grinding).

Errors in the depth of the stepped portion formed by trimming cause problems: if the depth is too shallow, the wall surface does not make a right angle after grinding (a sharp edge remains); and if the depth is too deep, it results in unnecessary cutting (extended processing time, excessive wear on cutting blades).

### SUMMARY OF THE INVENTION

A method according to the present disclosure is for processing a plate-shaped object having a chamfered portion formed at an outer peripheral edge thereof, in which a predetermined distance from the outer peripheral edge in a radial direction of the plate-shaped object and a predetermined depth from a front surface of the plate-shaped object are processed to remove at least a part of the chamfered portion. The method includes a preliminary processing step, a measurement step, and a main processing step. The preliminary processing step includes: rotating a chuck table that holds the plate-shaped object on a holding surface thereof about a rotation axis intersecting the holding surface; and performing, using a processing unit, at least one of processing the chamfered portion by a distance smaller than the predetermined distance or processing the chamfered portion by a depth shallower than the predetermined depth. The measurement step includes measuring at least one of a distance from the outer peripheral edge or a depth from the front surface of a region processed at the preliminary processing step. The main processing step includes: rotating the chuck table that holds the plate-shaped object on the holding surface thereof by at least 360 degrees about the rotation axis intersecting the holding surface; and performing, using the processing unit, at least one of processing the plate-shaped object up to the predetermined distance or processing the plate-shaped object up to the predetermined depth, based on at least one of the distance or the depth measured at the measurement step.

A method for manufacturing a semiconductor device chip according to another aspect of the present disclosure includes a preliminary processing step, a measurement step, a main processing step, a grinding step, and a division step. The preliminary processing step includes: rotating a chuck table that holds a plate-shaped object on a holding surface thereof about a rotation axis intersecting the holding surface, the plate-shaped object having semiconductor devices respectively formed in regions on a front surface partitioned by a plurality of intersecting division planned lines and a chamfered portion formed at an outer peripheral edge thereof; and performing, using a processing unit, at least one of processing the chamfered portion by a distance smaller than a predetermined distance or processing the chamfered portion by a depth shallower than a predetermined depth. The measurement step includes measuring at least one of a distance from the outer peripheral edge or a depth from the front surface of a region processed at the preliminary processing step. The main processing step includes: rotating the chuck table that holds the plate-shaped object on the holding surface thereof by at least 360 degrees about the rotation axis intersecting the holding surface; and performing, using the processing unit, at least one of processing the plate-shaped object up to the predetermined distance or processing the plate-shaped object up to the predetermined depth, based on at least one of the distance or the depth measured at the measurement step. The grinding step includes grinding a back surface of the plate-shaped object. The division step includes dividing the plate-shaped object along the planned division lines to manufacture semiconductor device chips.

A processing apparatus according to still another aspect of the present disclosure includes: a chuck table having a rotation axis intersecting a holding surface thereof; a processing unit that processes a plate-shaped object held on the chuck table; a measurement unit that measures a region processed by the processing unit; and a controller. The controller is configured to include: a processing region setting unit that sets a target processing region; a preliminary processing region setting unit that sets a preliminary processing region smaller than the target processing region; a correction calculation unit that calculates an amount of correction based on a region measured by the measurement unit and the preliminary processing region; and a correction command unit that corrects a processing position of the processing unit based on the amount of correction calculated by the correction calculation unit.

### BRIEF DESCRIPTION OF THE DRAWINGS

FIG. 1 is a perspective view schematically illustrating a configuration example of a processing apparatus according to a first embodiment;

FIG. 2 is a perspective view schematically illustrating a plate-shaped object to be processed by the processing apparatus illustrated in FIG. 1;

FIG. 3 is a cross-sectional view taken along line III-III in FIG. 2;

FIG. 4 is a flowchart illustrating a flow of a method for manufacturing a device chip according to the first embodiment;

FIG. 5 is a perspective view schematically illustrating a preliminary processing step of the method for manufacturing a device chip illustrated in FIG. 4;

FIG. 6 is a side view schematically illustrating, in a partial cross section, the preliminary processing step of the method for manufacturing a device chip illustrated in FIG. 4;

FIG. 7 is a plan view schematically illustrating a plate-shaped object after the preliminary processing step of the method for manufacturing a device chip illustrated in FIG. 4;

FIG. 8 is a cross-sectional view taken along line VIII-VIII in FIG. 7;

FIG. 9 is a perspective view schematically illustrating a measurement step of the method for manufacturing a device chip illustrated in FIG. 4;

FIG. 10 is a side view schematically illustrating, in a partial cross section, the measurement step of the method for manufacturing a device chip illustrated in FIG. 4;

FIG. 11 is a perspective view schematically illustrating a main processing step of the method for manufacturing a device chip illustrated in FIG. 4;

FIG. 12 is a side view schematically illustrating, in a partial cross section, the main processing step of the method for manufacturing a device chip illustrated in FIG. 4;

FIG. 13 is a plan view schematically illustrating a plate-shaped object after the main processing step of the method for manufacturing a device chip illustrated in FIG. 4;

FIG. 14 is a cross-sectional view taken along line XIV-XIV in FIG. 13;

FIG. 15 is a side view schematically illustrating, in a partial cross section, a grinding step of the method for manufacturing a device chip illustrated in FIG. 4;

FIG. 16 is a perspective view schematically illustrating a division step of the method for manufacturing a device chip illustrated in FIG. 4;

FIG. 17 is a flowchart illustrating a flow of a method for manufacturing a device chip according to a first modification example of the first embodiment;

FIG. 18 is a plan view schematically illustrating a preliminary processing step and a measurement step of the method for manufacturing a device chip illustrated in FIG. 17;

FIG. 19 is a plan view schematically illustrating another example of a plate-shaped object after the preliminary processing step of the method for manufacturing a device chip illustrated in FIG. 17; and

FIG. 20 is a perspective view schematically illustrating a preliminary processing step and a main processing step of a method for manufacturing a device chip according to a second modification example of the first embodiment.

### DETAILED DESCRIPTION OF THE PREFERRED EMBODIMENTS

Embodiments of the present invention will now be described in detail with reference to the drawings. The present invention is not limited by the contents described in the following embodiments. The components described below include those that can be easily assumed by those skilled in the art and those that are substantially the same. The configurations described below can be combined as appropriate. Various omissions, substitutions, or changes of configurations can be made without departing from the gist of the present invention.

### First Embodiment

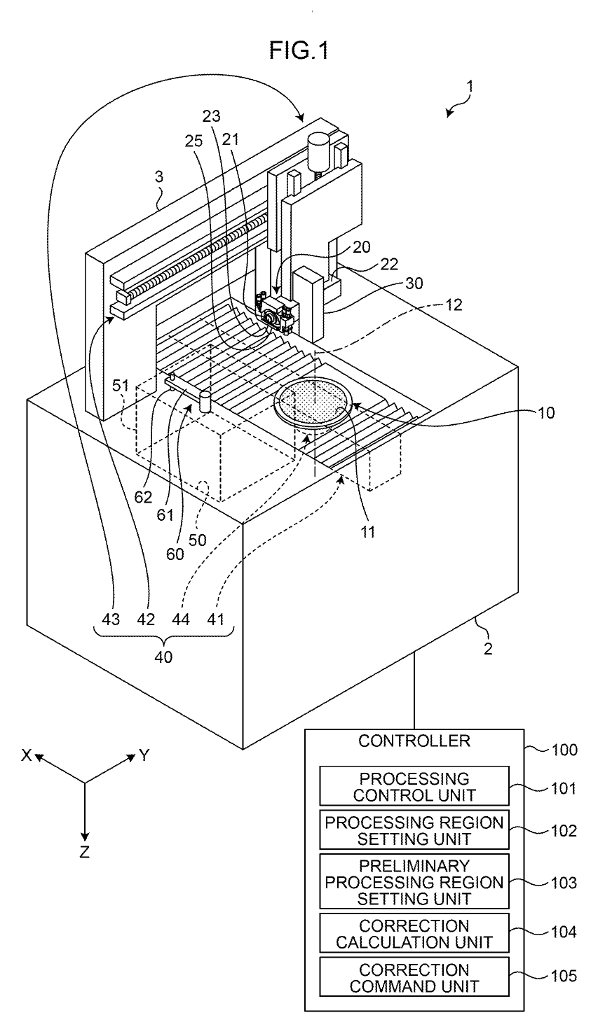

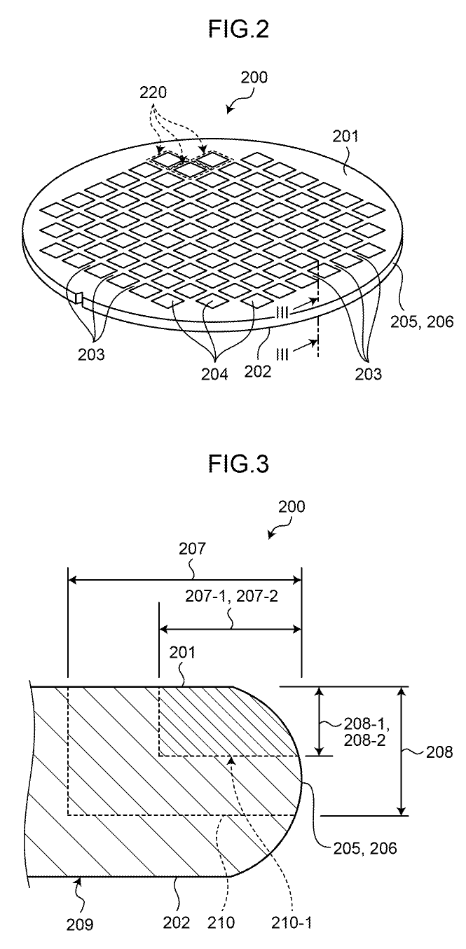

A processing apparatus according to a first embodiment of the present invention will now be described based on the drawings. FIG. 1 is a perspective view schematically illustrating a configuration example of a processing apparatus according to the first embodiment. FIG. 2 is a perspective view schematically illustrating a plate-shaped object to be processed by the processing apparatus illustrated in FIG. 1. FIG. 3 is a cross-sectional view taken along line III-III in FIG. 2.

### Workpiece

A processing apparatus 1 illustrated in FIG. 1 according to the first embodiment is a cutting apparatus that cuts a plate-shaped object 200 illustrated in FIG. 2. The plate-shaped object 200 to be processed by the processing apparatus 1 is a wafer such as a disk-shaped semiconductor wafer or an optical device wafer using silicon, gallium nitride, gallium arsenide, silicon carbide (SiC), sapphire, or the like as a substrate. As illustrated in FIG. 2, the plate-shaped object 200 includes a disk-shaped disk portion 209 having a circular front surface 201 and a circular back surface 202 that is the back surface of the front surface 201 and is parallel to the front surface 201, and a chamfered portion 205 continuous with the outer edge of the disk portion 209.

In the plate-shaped object 200, devices 204 are respectively formed in regions partitioned in a lattice form by a plurality of planned division lines 203 formed in a lattice form on the front surface 201. The device 204 is, for example, an integrated circuit such as an integrated circuit (IC) or a large-scale integration (LSI), an image sensor such as a charge-coupled device (CCD) or a complementary metal-oxide-semiconductor (CMOS), or a memory (a semiconductor storage device).

As illustrated in FIG. 3, the plate-shaped object 200 has the chamfered portion 205 formed at its outer edge 206 (corresponding to an outer peripheral edge). The chamfered portion 205 is formed from the front surface 201 to the back surface 202, and is formed to have an arcuate cross section such that the center in the thickness direction is located most on the outer circumferential side. The plate-shaped object 200 has the chamfered portion 205, so that each of the diameters of the front surface 201 and the back surface 202 are set smaller than the maximum outer diameter (the diameter at the center in the thickness direction) of the plate-shaped object 200.

The plate-shaped object 200 is processed by a predetermined distance 207 from the outer edge 206 and by a predetermined depth 208 from the front surface 201 of the plate-shaped object 200, and at least a part 210 (indicated by the dense parallel oblique lines in FIG. 3) on the front surface 201 side of the disk portion 209 and the chamfered portion 205 is removed over the entire circumference. After the part 210 of the disk portion 209 and the chamfered portion 205 is removed, the plate-shaped object 200 is thinned to a predetermined thickness by the back surface 202 side being ground or the like, and the chamfered portion 205 is removed. The plate-shaped object 200 is then divided into individual device chips 220 along the planned division lines 203.

In the first embodiment, the predetermined depth 208 is a depth that exceeds the center in the thickness direction from the front surface 201 and reaches a portion more on the back surface 202 side than the center in the thickness direction, and is deeper than the predetermined thickness. The device chip 220 includes a part of the substrate and the device 204. In the first embodiment, the predetermined distance 207 is, for example, 3000 μm, and the predetermined depth 208 is, for example, 500 μm.

In the first embodiment, the device 204 is a semiconductor device such as an IC, an LSI, or a memory, and the device chip 220 is a semiconductor device chip.

### Processing Apparatus

Next, the processing apparatus 1 illustrated in FIG. 1 is described. The processing apparatus 1 illustrated in FIG. 1 is a cutting apparatus in which a chuck table 10 holds the plate-shaped object 200 and a cutting blade 21 cuts the outer edge 206 of the plate-shaped object 200, so as to remove, from the front surface 201 side of the plate-shaped object 200, the part 210 of the chamfered portion 205 described above over the entire circumference. As illustrated in FIG. 1, the processing apparatus 1 includes: the chuck table 10 that sucks and holds the plate-shaped object 200 on its holding surface 11; a cutting unit 20 (corresponding to a processing unit) that cuts the plate-shaped object 200 held by the chuck table 10 using the cutting blade 21; an imaging unit 30 that images the plate-shaped object 200 held on the chuck table 10; and a controller 100.

As illustrated in FIG. 1, the processing apparatus 1 includes a movement unit 40 that moves the cutting unit 20 relative to the plate-shaped object 200 held on the chuck table 10. The movement unit 40 includes: an X-axis movement unit 41 that performs processing feeding of the chuck table 10 in an X-axis direction parallel to the horizontal direction; a Y-axis movement unit 42 that performs indexing feeding of the cutting unit 20 in a Y-axis direction parallel to the horizontal direction and orthogonal to the X-axis direction; a Z-axis movement unit 43 that performs cutting-in feeding of the cutting unit 20 in a Z-axis direction orthogonal to both the X-axis direction and the Y-axis direction and parallel to the vertical direction; and a rotational movement unit 44 that rotates the chuck table 10 about a rotation axis 12 (indicated by the alternate long and short dash line in FIG. 1) parallel to the Z-axis direction, which intersects (in the first embodiment, is orthogonal to) the holding surface 11.

The X-axis movement unit 41 moves the chuck table 10 in the X-axis direction, which is the processing feeding direction, and thereby performs relative processing feeding of the chuck table 10 and the cutting unit 20 along the X-axis direction. The Y-axis movement unit 42 moves the cutting unit 20 in the Y-axis direction, which is the indexing feeding direction, and thereby performs relative indexing feeding of the chuck table 10 and the cutting unit 20 along the Y-axis direction. The Z-axis movement unit 43 moves the cutting unit 20 in the Z-axis direction, which is the cutting-in feeding direction, and thereby performs relative cutting-in feeding of the chuck table 10 and the cutting unit 20 along the Z-axis direction.

Each of the X-axis movement unit 41, the Y-axis movement unit 42, and the Z-axis movement unit 43 includes a known ball screw provided to be rotatable about the axis, a known motor that rotates the ball screw about the axis, and a known guide rail that supports the chuck table 10 or the cutting unit 20 such that the chuck table 10 or the cutting unit 20 is movable in the X-axis direction, the Y-axis direction, or the Z-axis direction. The rotational movement unit 44 includes a motor or the like that rotates the chuck table 10 about the rotation axis 12.

The chuck table 10 is in a disc shape, and the holding surface 11 (corresponding to an attraction region) that holds the plate-shaped object 200 is formed of a porous ceramic or the like. That is, the chuck table 10 has the holding surface 11. The outer diameter of the holding surface 11 is substantially equal (in the first embodiment, equal) to each of the outer diameters of the front surface 201 and the back surface 202 of the plate-shaped object 200. The chuck table 10 is provided to, by means of the X-axis movement unit 41, be movable in the X-axis direction throughout a processing region under the cutting unit 20 and a carrying-in/out region that is apart from under the cutting unit 20 and where the plate-shaped object 200 is carried in or out, and is provided to, by means of the rotational movement unit 44, be rotatable about the rotation axis 12 parallel to the Z-axis direction. That is, the chuck table 10 has the rotation axis 12.

In the chuck table 10, the holding surface 11 is connected to a not-illustrated suction source; by the holding surface 11 being sucked by the suction source, the chuck table 10 sucks and holds the plate-shaped object 200 mounted on the holding surface 11. In the first embodiment, the chuck table 10 sucks and holds the back surface 202 side of the plate-shaped object 200.

The cutting unit 20 is a processing unit including a spindle 23 to which a cutting blade 21 that cuts the plate-shaped object 200 held by the chuck table 10 is fixed in an attachable and detachable manner. Relative to the plate-shaped object 200 held on the chuck table 10, the cutting unit 20 is provided to be movable in the Y-axis direction by means of the Y-axis movement unit 42, and is provided to be movable in the Z-axis direction by means of the Z-axis movement unit 43.

The cutting unit 20 is provided on a gate-shaped support frame 3 erected from an apparatus body 2, via the Y-axis movement unit 42, the Z-axis movement unit 43, etc. In the cutting unit 20, the cutting blade 21 can be positioned at an arbitrary position of the holding surface 11 of the chuck table 10 by the Y-axis movement unit 42 and the Z-axis movement unit 43.

The cutting unit 20 includes the cutting blade 21, a spindle housing 22 provided to be movable in the Y-axis direction and the Z-axis direction by means of the Y-axis movement unit 42 and the Z-axis movement unit 43, a spindle 23 provided in the spindle housing 22 to be rotatable about the axis, a not-illustrated spindle motor that rotates the spindle 23 about the axis, and a cutting water supply nozzle 25 that supplies cutting water to the cutting blade 21, etc.

The cutting blade 21 is an ultrathin cutting grindstone having a substantially ring shape, and cuts the plate-shaped object 200 held on the chuck table 10 in an annular shape along the outer periphery of the plate-shaped object 200. In the first embodiment, the cutting blade 21 includes a circular ring-shaped cutting edge that cuts the plate-shaped object 200, and a circular ring-shaped annular base that supports the cutting edge at the outer edge and is installed to be attachable to and detachable from the spindle 23.

The cutting edge is composed of abrasive grains of diamond, cubic boron nitride (CBN), or the like and a bond material (bonding material) such as metal or resin, and is formed with a predetermined thickness. In the present invention, the cutting blade 21 may be what is called a washer blade formed only of a cutting edge. In the first embodiment, the extremity of the cutting edge is formed flat along the Y-axis direction. In the first embodiment, the thickness of the cutting edge is thicker (longer) than the predetermined distance 207.

The spindle housing 22 is supported by the Z-axis movement unit 43 to be movable in the Z-axis direction, and is supported by the Y-axis movement unit 42 via the Z-axis movement unit 43 to be movable in the Y-axis direction. The spindle housing 22 accommodates a portion excluding a distal end portion of the spindle 23, a not-illustrated spindle motor, etc., and supports the spindle 23 such that the spindle 23 is rotatable about the axis.

The spindle 23 fixes the cutting blade 21 to the distal end thereof. The spindle 23 is rotated by the not-illustrated spindle motor, and a distal end portion of the spindle 23 protrudes from the distal end surface of the spindle housing 22. The distal end portion of the spindle 23 is formed to be gradually thinner toward the distal end, and the cutting blade 21 is fixed to the distal end portion.

The axes of the spindle 23 and the cutting blade 21 of the cutting unit 20 are set parallel to the Y-axis direction.

The imaging unit 30 is fixed to the cutting unit 20 so as to move integrally with the cutting unit 20. The imaging unit 30 includes an imaging element that images a region to be cut of the plate-shaped object 200 before cutting held on the chuck table 10. The imaging element is, for example, a charge-coupled device (CCD) imaging element or a complementary MOS (CMOS) imaging element. The imaging unit 30 photographs the plate-shaped object 200 held on the chuck table 10, thus obtains an image used for the purpose of executing alignment of aligning the plate-shaped object 200 and the cutting blade 21, and for other purposes, and outputs the obtained image to the controller 100.

The processing apparatus 1 includes a not-illustrated X-axis direction position detection unit for detecting the position in the X-axis direction of the chuck table 10, a not-illustrated Y-axis direction position detection unit for detecting the position in the Y-axis direction of the cutting unit 20, and a Z-axis direction position detection unit for detecting the position in the Z-axis direction of the cutting unit 20. Each of the X-axis direction position detection unit and the Y-axis direction position detection unit can be composed of a linear scale parallel to the X-axis direction or the Y-axis direction and a reading head. The Z-axis direction position detection unit detects the position in the Z-axis direction of the cutting unit 20 with pulses of a motor.

The X-axis direction position detection unit, the Y-axis direction position detection unit, and the Z-axis direction position detection unit output, to the controller 100, the position in the X-axis direction of the chuck table 10 and the position in the Y-axis direction or the Z-axis direction of the cutting unit 20. In the first embodiment, the positions in the X-axis direction, the Y-axis direction, and the Z-axis direction of each component of the processing apparatus 1 are determined by positions using, as references, not-illustrated reference positions determined in advance. The reference position in the Z-axis direction is a position of the cutting unit 20 when the lower end of the cutting edge of the cutting blade 21 is located on the same plane as the holding surface 11.

The processing apparatus 1 includes a cassette elevator 50 on which a cassette 51 accommodating plate-shaped objects 200 before and after cutting is mounted and that moves the cassette 51 in the Z-axis direction, and a not-illustrated conveyance unit that conveys the plate-shaped object 200 between the cassette 51 and the chuck table 10.

Further, as illustrated in FIG. 1, the processing apparatus 1 includes a measurement unit 60. The measurement unit 60 measures the thickness of the region, cut by the cutting unit 20, of the plate-shaped object 200. In the first embodiment, the measurement unit 60 is what is called a non-contact gauge (non-contact thickness measurement instrument) that irradiates the plate-shaped object 200 with ultrasonic waves, light, or the like without coming into contact with the plate-shaped object 200 and measures information according to the thickness of the region cut by the cutting unit 20.

In the first embodiment, in the measurement unit 60, the range of measurable thickness of the plate-shaped object 200 is determined in advance, and the thickness of the plate-shaped object 200 before cutting exceeds the measurable range of the measurement unit 60. The measurement unit 60 outputs the measurement result to the controller 100.

The measurement unit 60 is placed next to the chuck table 10 positioned in the processing region. The measurement unit 60 includes a straight measurement arm 61 provided on the apparatus body 2 such that the proximal end thereof is swingable around an axis parallel to the Z-axis direction, a measurement element 62 that is placed at the distal end of the measurement arm 61 and that applies ultrasonic waves, light, or the like toward the plate-shaped object 200 held on the chuck table 10 and receives the reflected ultrasonic waves or light, and a not-illustrated angle detection unit that detects the orientation around the axis of the measurement arm 61.

The measurement unit 60 applies ultrasonic waves, light, or the like from the measurement element 62 toward the plate-shaped object 200 held on the chuck table 10 while swinging the measurement arm 61 around the proximal end, associates information received by the measurement element 62, that is, information according to the thickness of the plate-shaped object 200 with the orientation of the measurement arm 61 detected by the angle detection unit on a one-to-one basis, and outputs the measurement result to the controller 100. The measurement unit 60 associates information according to the thickness of the plate-shaped object 200 with the orientation of the measurement arm 61 detected by the angle detection unit on a one-to-one basis, and measures information according to the thickness of the plate-shaped object 200.

The controller 100 controls each component of the processing apparatus 1 to cause the processing apparatus 1 to perform a processing operation on the plate-shaped object 200. The controller 100 is a computer including an arithmetic processing device including a microprocessor such as a central processing unit (CPU), a storage device including a memory such as a read-only memory (ROM) or a random-access memory (RAM), and an input/output interface device. The arithmetic processing device of the controller 100 performs arithmetic processing according to a computer program stored in the storage device, and outputs a control signal for controlling the processing apparatus 1 to each component of the processing apparatus 1 via the input/output interface device.

The controller 100 is connected to a display unit formed of a liquid crystal display device or the like that displays a state of a processing operation, an image, etc., an input unit used when an operator registers processing content information, etc., and a notification unit. The input unit is formed of at least one of a touch panel provided on the display unit or an external input device such as a keyboard. The notification unit emits at least one of sound or light to notify the operator.

As illustrated in FIG. 1, the controller 100 includes a processing control unit 101, a processing region setting unit 102, a preliminary processing region setting unit 103, a correction calculation unit 104, and a correction command unit 105. The processing control unit 101 controls each component of the processing apparatus 1 to cause the processing apparatus 1 to perform a processing operation on the plate-shaped object 200.

The processing region setting unit 102 sets and stores a target processing region. In the first embodiment, the processing region setting unit 102 sets and stores a predetermined distance 207, which is the target processing region, from the outer edge 206 of the part 210 to be removed of the disk portion 209 and the chamfered portion 205 in a direction parallel to the holding surface 11, and a predetermined depth 208, which is the target processing region, from the front surface 201 of the part 210 to be removed of the disk portion 209 and the chamfered portion 205 in a direction intersecting (in the first embodiment, orthogonal to) the holding surface 11.

The preliminary processing region setting unit 103 sets and stores a preliminary processing region smaller than the target processing region. In the first embodiment, the preliminary processing region setting unit 103 sets and stores a preliminary processing distance 207-1 (illustrated in FIG. 3), which is the preliminary processing region, shorter (smaller) than the predetermined distance 207 from the outer edge 206 in a direction parallel to the holding surface 11, and a preliminary processing depth 208-1 (illustrated in FIG. 3), which is the preliminary processing region, shallower than the predetermined depth 208 from the front surface 201 in a direction intersecting (in the first embodiment, orthogonal to) the holding surface 11.

In the first embodiment, the thickness of the chamfered portion 205 after the preliminary processing depth 208-1 is removed from the front surface 201 is included in the measurable range of the measurement unit 60. In the first embodiment, the preliminary processing distance 207-1 is 500 μm, and the preliminary processing depth 208-1 is 10 μm.

The correction calculation unit 104 calculates the amount of correction from the region measured by the measurement unit 60 and the preliminary processing region. After the cutting edge of the cutting blade 21 is caused to cut into the outer edge 206 of the plate-shaped object 200 held on the chuck table 10 and at least a portion 210-1 (indicated by the denser oblique lines in FIG. 3) in the circumferential direction of the outer edge 206 of the plate-shaped object 200 is removed by the preliminary processing distance 207-1 and the preliminary processing depth 208-1, the correction calculation unit 104 calculates, based on the result of measurement by the measurement unit 60, a distance 207-2 (illustrated in FIG. 3) from the outer edge 206 and a depth 208-2 (illustrated in FIG. 3) from the front surface 201 of the actually removed portion 210-1 of the outer edge of the disk portion 209 and the chamfered portion 205.

The correction calculation unit 104 calculates the difference between the preliminary processing distance 207-1 and the distance 207-2 as an amount of correction, and calculates the difference between the preliminary processing depth 208-1 and the depth 208-2 as an amount of correction. The portion 210-1 of the outer edge of the disk portion 209 and the chamfered portion 205 is included in the part 210 of the outer edge of the disk portion 209 and the chamfered portion 205, and is a region smaller than the part 210.

The correction command unit 105 corrects the processing position of the cutting unit 20 based on the difference that is the amount of correction calculated by the correction calculation unit 104. In the case where the preliminary processing distance 207-1 is larger than the distance 207-2, the correction command unit 105 corrects the position of the cutting blade 21 of the cutting unit 20 so that the cutting edge cuts into a position having a value obtained by adding, to the predetermined distance 207, the difference that is the amount of correction described above. In the case where the distance 207-2 is larger than the preliminary processing distance 207-1, the correction command unit 105 corrects the position of the cutting blade 21 of the cutting unit 20 so that the cutting edge cuts into a position having a value obtained by subtracting, from the predetermined distance 207, the difference that is the amount of correction described above.

In the case where the preliminary processing depth 208-1 is deeper than the depth 208-2, the correction command unit 105 corrects the position of the cutting blade 21 of the cutting unit 20 so that the cutting edge cuts into a position having a value obtained by adding, to the predetermined depth 208, the difference that is the amount of correction described above. In the case where the depth 208-2 is deeper than the preliminary processing depth 208-1, the correction command unit 105 corrects the position of the cutting blade 21 of the cutting unit 20 so that the cutting edge cuts into a position having a value obtained by subtracting, from the predetermined depth 208, the difference that is the amount of correction described above.

The functions of the processing region setting unit 102 and the preliminary processing region setting unit 103 are implemented by the storage device described above. The functions of the processing control unit 101, the correction calculation unit 104, and the correction command unit 105 are implemented by the arithmetic processing device described above performing arithmetic processing according to a computer program stored in the storage device.

### Method for Manufacturing Device Chip

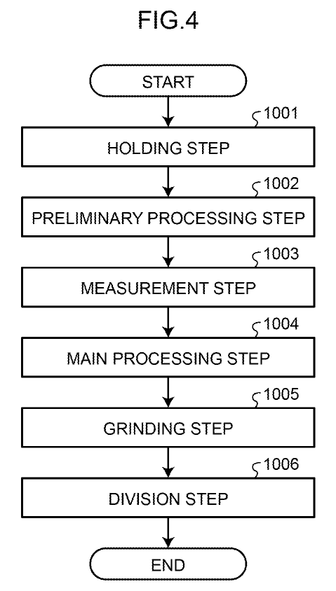

Next, a method for manufacturing a device chip according to the first embodiment is described. FIG. 4 is a flowchart illustrating a flow of a method for manufacturing a device chip according to the first embodiment. The method for manufacturing a device chip according to the first embodiment is a method for manufacturing a semiconductor device chip, and includes, as illustrated in FIG. 4, a holding step 1001, a preliminary processing step 1002, a measurement step 1003, a main processing step 1004, a grinding step 1005, and a division step 1006.

The holding step 1001, the preliminary processing step 1002, the measurement step 1003, and the main processing step 1004 are performed by the processing apparatus 1 of the configuration described above.

In the processing apparatus 1, the processing control unit 101 of the controller 100 receives processing conditions inputted from the input unit or the like, and stores the processing conditions in the storage device. The processing conditions include the thickness of the plate-shaped object 200 before cutting, the predetermined distance 207, the predetermined depth 208, the preliminary processing distance 207-1, and the preliminary processing depth 208-1. In the processing apparatus 1, the processing region setting unit 102 of the controller 100 stores the predetermined distance 207 and the predetermined depth 208 inputted from the input unit or the like.

In the processing apparatus 1, the preliminary processing region setting unit 103 of the controller 100 stores the preliminary processing distance 207-1 and the preliminary processing depth 208-1 inputted from the input unit or the like. In the processing apparatus 1, the cassette 51 accommodating plate-shaped objects 200 is placed on the cassette elevator 50. When the processing control unit 101 of the controller 100 receives a processing start instruction inputted from the input unit or the like, the processing apparatus 1 starts a processing operation, that is, the holding step 1001.

### Holding Step

The holding step 1001 is a step of holding the plate-shaped object 200 on the holding surface 11 of the chuck table 10. In the first embodiment, at the holding step 1001, in the processing apparatus 1, the processing control unit 101 of the controller 100 controls the conveyance unit to take out one plate-shaped object 200 from the cassette 51 and mount the back surface 202 of the plate-shaped object 200 on the holding surface 11 of the chuck table 10 in the carrying-in/out region.

In the first embodiment, at the holding step 1001, in the processing apparatus 1, the processing control unit 101 of the controller 100 sucks and holds the back surface 202 of the plate-shaped object 200 on the holding surface 11 of the chuck table 10. In the first embodiment, in the processing apparatus 1, the processing control unit 101 of the controller 100 starts rotation of the spindle 23 of the cutting unit 20, and starts supply of cutting water to the cutting blade 21.

### Preliminary Processing Step

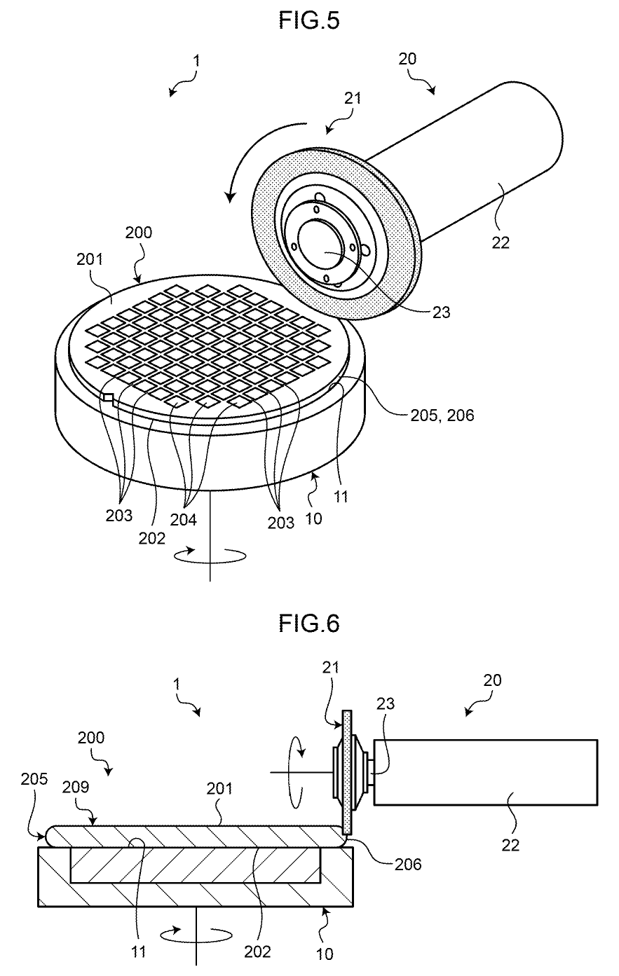

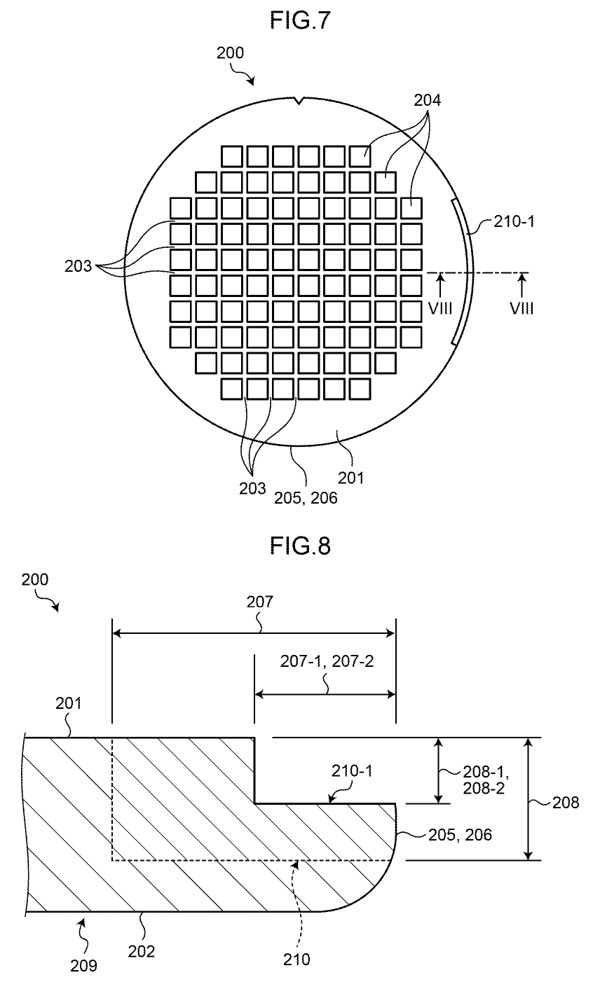

FIG. 5 is a perspective view schematically illustrating the preliminary processing step of the method for manufacturing a device chip illustrated in FIG. 4. FIG. 6 is a side view schematically illustrating, in a partial cross section, the preliminary processing step of the method for manufacturing a device chip illustrated in FIG. 4. FIG. 7 is a plan view schematically illustrating a plate-shaped object after the preliminary processing step of the method for manufacturing a device chip illustrated in FIG. 4. FIG. 8 is a cross-sectional view taken along line VIII-VIII in FIG. 7.

The preliminary processing step 1002 is a step of rotating the chuck table 10 that holds the plate-shaped object 200 on the holding surface 11 about the rotation axis 12 intersecting the holding surface 11, and performing, using the cutting unit 20, at least one of processing the chamfered portion 205 by a distance smaller than the predetermined distance 207 or processing the chamfered portion 205 by a depth shallower than the predetermined depth 208.

In the first embodiment, at the preliminary processing step 1002, in the processing apparatus 1, the processing control unit 101 of the controller 100 controls the movement unit 40 to move the chuck table 10 toward the processing region. In the first embodiment, at the preliminary processing step 1002, in the processing apparatus 1, the processing control unit 101 of the controller 100 causes the imaging unit 30 to image the plate-shaped object 200 sucked and held by the chuck table 10, and executes alignment based on an image or the like acquired by imaging.

In the first embodiment, at the preliminary processing step 1002, in the processing apparatus 1, as illustrated in FIGS. 5 and 6, the processing control unit 101 of the controller 100 rotates the chuck table 10 about the rotation axis 12 while causing the cutting edge of the cutting blade 21 to cut in by the preliminary processing distance 207-1 from the outer edge 206 of the plate-shaped object 200 and by the preliminary processing depth 208-1 from the front surface 201 of the plate-shaped object 200, and thus removes a portion 210-1 on the front surface 201 side of the disk portion 209 and the chamfered portion 205 of the plate-shaped object 200. In the first embodiment, at the preliminary processing step 1002, as illustrated in FIGS. 7 and 8, not the entire circumference of the outer edge 206 of the plate-shaped object 200 but a portion 210-1 of the disk portion 209 and the chamfered portion 205 is removed in a part of the circumferential direction.

In this manner, in the first embodiment, the preliminary processing step 1002 includes rotating the chuck table 10 that holds the plate-shaped object 200 on the holding surface 11 about the rotation axis 12 intersecting the holding surface 11, and performing, using the cutting unit 20, both of processing the chamfered portion 205 by a distance smaller than the predetermined distance 207 and processing the chamfered portion 205 by a depth shallower than the predetermined depth 208.

### Measurement Step

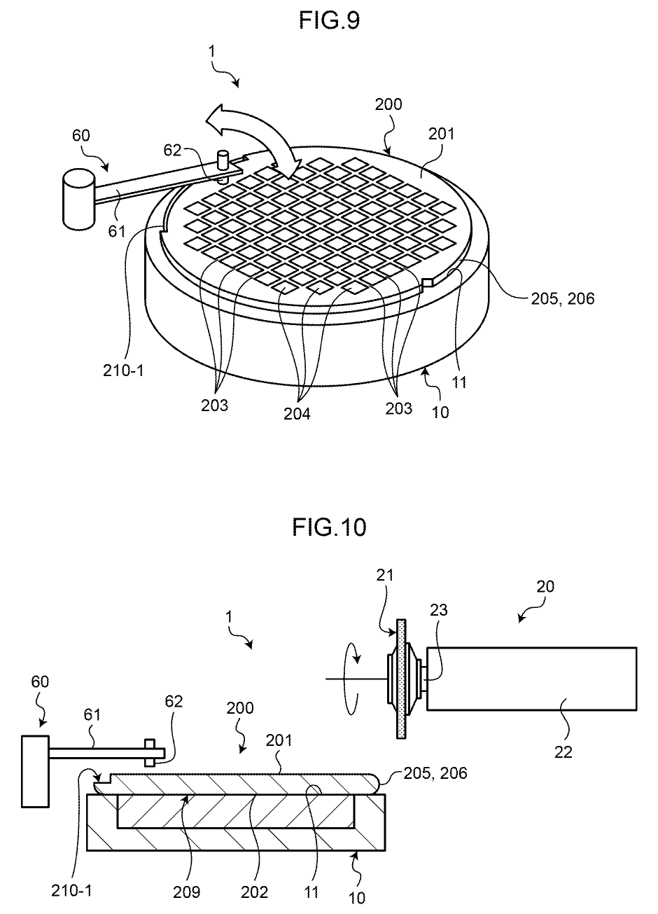

FIG. 9 is a perspective view schematically illustrating the measurement step of the method for manufacturing a device chip illustrated in FIG. 4. FIG. 10 is a side view schematically illustrating, in a partial cross section, the measurement step of the method for manufacturing a device chip illustrated in FIG. 4. The measurement step 1003 is a step of measuring at least one of the distance 207-2 from the outer edge 206 and the depth 208-2 from the front surface 201 of the portion 210-1 of the disk portion 209 and the chamfered portion 205 processed at the preliminary processing step 1002.

In the first embodiment, at the measurement step 1003, in the processing apparatus 1, the processing control unit 101 of the controller 100 retracts the cutting unit 20 from the chuck table 10. In the first embodiment, at the measurement step 1003, in the processing apparatus 1, the processing control unit 101 of the controller 100 rotates the chuck table 10 about the rotation axis 12 to cause the portion 210-1 of the disk portion 209 and the chamfered portion 205, which is the region processed at the preliminary processing step 1002 of the plate-shaped object 200, to be positioned under the locus of the measurement element 62 when swinging the measurement arm 61 of the measurement unit 60, and stops the rotation of the chuck table 10.

In the first embodiment, at the measurement step 1003, in the processing apparatus 1, as illustrated in FIGS. 9 and 10, the correction calculation unit 104 of the controller 100 applies ultrasonic waves, light, or the like from the measurement element 62 while swinging the measurement arm 61. In the first embodiment, at the measurement step 1003, in the processing apparatus 1, the correction calculation unit 104 of the controller 100 applies ultrasonic waves, light, or the like from the measurement element 62 while swinging the measurement arm 61 such that the measurement element 62 is located over an area from a position more on the inner circumferential side than the portion 210-1 of the disk portion 209 and the chamfered portion 205 processed at the preliminary processing step 1002 to a position more on the outer circumferential side than the outer edge 206 of the plate-shaped object 200, and outputs the measurement result to the controller 100.

To this end, in the first embodiment, at the measurement step 1003, in the processing apparatus 1, the correction calculation unit 104 of the controller 100 determines whether or not the position is located on the portion 210-1 of the disk portion 209 and the chamfered portion 205 based on whether or not the measurement unit 60 successfully measures the thickness of the plate-shaped object 200, and calculates the distance 207-2 based on the orientation of the measurement arm 61 associated with information regarding the thickness. Further, in the first embodiment, at the measurement step 1003, in the processing apparatus 1, the correction calculation unit 104 of the controller 100 calculates the depth 208-2 described above from the thickness of the portion 210-1 of the chamfered portion 205 where the measurement unit 60 successfully measures the thickness of the plate-shaped object 200, and the thickness of the plate-shaped object 200 before cutting.

In this manner, in the first embodiment, the measurement step 1003 includes measuring both the distance 207-2 from the outer edge 206 and the depth 208-2 from the front surface 201 of the portion 210-1 of the disk portion 209 and the chamfered portion 205 processed at the preliminary processing step 1002. In the present invention, the range of the thickness of the plate-shaped object 200 measurable by the measurement unit 60 may be included in the thickness of the plate-shaped object 200 before cutting, and the correction calculation unit 104 may calculate the distance 207-2 and the depth 208-2 described above based on the measurement result of the measurement unit 60. In the present invention, the correction calculation unit 104 may determine whether or not the position is located on the portion 210-1 of the disk portion 209 and the chamfered portion 205 based on the amount of light or the intensity of ultrasonic waves received by the measurement unit 60, and calculate the distance 207-2 and the depth 208-2 described above.

### Main Processing Step

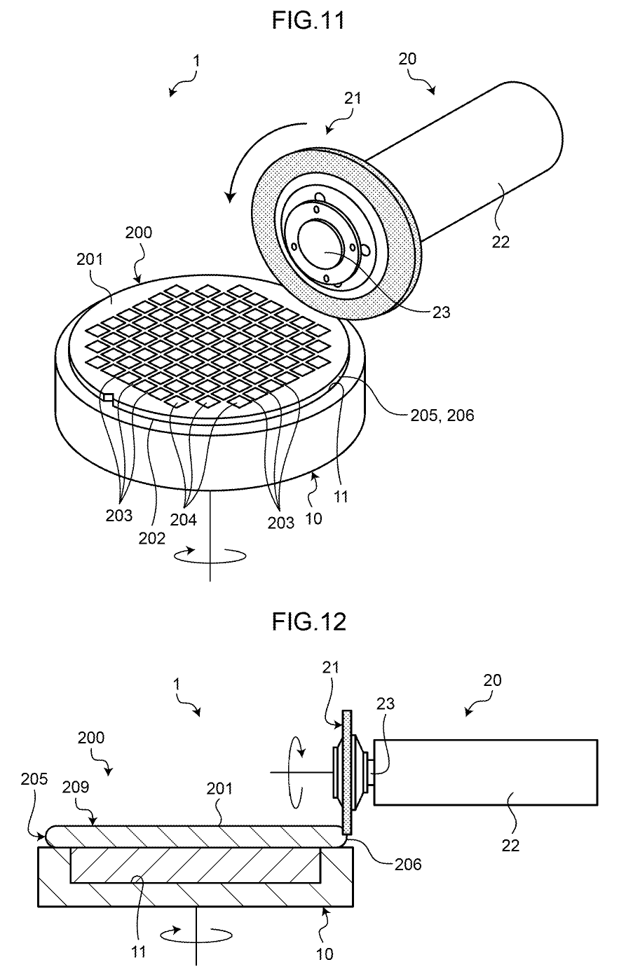

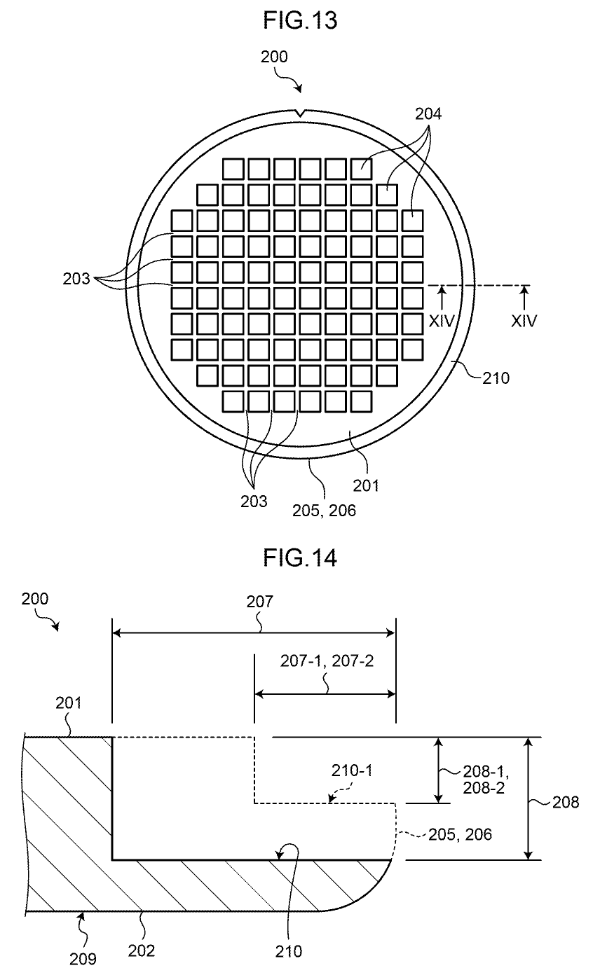

FIG. 11 is a perspective view schematically illustrating the main processing step of the method for manufacturing a device chip illustrated in FIG. 4. FIG. 12 is a side view schematically illustrating, in a partial cross section, the main processing step of the method for manufacturing a device chip illustrated in FIG. 4. FIG. 13 is a plan view schematically illustrating a plate-shaped object after the main processing step of the method for manufacturing a device chip illustrated in FIG. 4. FIG. 14 is a cross-sectional view taken along line XIV-XIV in FIG. 13.

The main processing step 1004 is a step of rotating the chuck table 10 that holds the plate-shaped object 200 on the holding surface 11 by at least 360 degrees about the rotation axis 12 intersecting the holding surface 11, and performing, using the cutting unit 20, at least one of cutting (processing) the plate-shaped object 200 up to the predetermined distance 207 or cutting (processing) the plate-shaped object 200 up to the predetermined depth 208, based on at least one of the distance 207-2 or the depth 208-2 measured at the measurement step 1003.

In the first embodiment, at the main processing step 1004, in the processing apparatus 1, the correction calculation unit 104 of the controller 100 calculates the difference between the preliminary processing distance 207-1 and the distance 207-2 as an amount of correction, and calculates the difference between the preliminary processing depth 208-1 and the depth 208-2 as an amount of correction. In the first embodiment, at the main processing step 1004, in the processing apparatus 1, in the case where the preliminary processing distance 207-1 is larger than the distance 207-2, the correction command unit 105 of the controller 100 corrects the position of the cutting blade 21 of the cutting unit 20 at the main processing step 1004 so that the cutting edge cuts into a position having a value obtained by adding, to the predetermined distance 207, the difference that is the amount of correction described above. In the first embodiment, at the main processing step 1004, in the processing apparatus 1, in the case where the distance 207-2 is larger than the preliminary processing distance 207-1, the correction command unit 105 of the controller 100 corrects the position of the cutting blade 21 of the cutting unit 20 at the main processing step 1004 so that the cutting edge cuts into a position having a value obtained by subtracting, from the predetermined distance 207, the difference that is the amount of correction described above.

In the first embodiment, at the main processing step 1004, in the processing apparatus 1, in the case where the preliminary processing depth 208-1 is deeper than the depth 208-2, the correction command unit 105 of the controller 100 corrects the position of the cutting blade 21 of the cutting unit 20 at the main processing step 1004 so that the cutting edge cuts into a position having a value obtained by adding, to the predetermined depth 208, the difference that is the amount of correction described above. In the first embodiment, at the main processing step 1004, in the processing apparatus 1, in the case where the depth 208-2 is deeper than the preliminary processing depth 208-1, the correction command unit 105 of the controller 100 corrects the position of the cutting blade 21 of the cutting unit 20 at the main processing step 1004 so that the cutting edge cuts into a position having a value obtained by subtracting, from the predetermined depth 208, the difference that is the amount of correction described above.

In the first embodiment, at the main processing step 1004, in the processing apparatus 1, the processing control unit 101 of the controller 100, as illustrated in FIGS. 11 and 12, makes at least one rotation of the chuck table 10 about the rotation axis 12 while causing the cutting edge of the cutting blade 21 to cut in by a distance obtained by correcting, with the difference described above, the predetermined distance 207 from the outer edge 206 of the plate-shaped object 200 and by a depth obtained by correcting, with the difference described above, the predetermined depth 208 from the front surface 201 of the plate-shaped object 200, and as illustrated in FIGS. 13 and 14, removes, from the front surface 201 side of the chamfered portion 205 of the outer edge 206 of the plate-shaped object 200, a part 210 of the chamfered portion 205 over the entire circumference.

In this manner, in the first embodiment, the main processing step 1004 includes rotating the chuck table 10 that holds the plate-shaped object 200 on the holding surface 11 by at least 360 degrees about the rotation axis 12 intersecting the holding surface 11, and performing, using the cutting unit 20, both cutting (processing) the plate-shaped object 200 up to the predetermined distance 207 and cutting (processing) the plate-shaped object 200 up to the predetermined depth 208 corrected. In the first embodiment, as described above, in the preliminary processing step 1002 and the main processing step 1004, the chamfered portion 205 is cut with the cutting blade 21 attached to the distal end of the spindle 23.

The preliminary processing step 1002, the measurement step 1003, and the main processing step 1004 constitute a method for processing a plate-shaped object having a chamfered portion 205 formed at the outer edge 206, in which a predetermined distance 207 from the outer edge 206 in the radial direction of the plate-shaped object 200 and a predetermined depth 208 from the front surface 201 of the plate-shaped object 200 are cut (processed) to remove at least a part 210 of the chamfered portion 205. Thus, the method for processing a plate-shaped object includes the preliminary processing step 1002, the measurement step 1003, and the main processing step 1004.

The processing apparatus 1 sequentially performs the holding step 1001, the preliminary processing step 1002, the measurement step 1003, and the main processing step 1004 on plate-shaped objects 200 in the cassette 51 one by one. The processing apparatus 1 sequentially performs the holding step 1001, the preliminary processing step 1002, the measurement step 1003, and the main processing step 1004 on all the plate-shaped objects 200 in the cassette 51, and ends the processing operation.

### Grinding Step

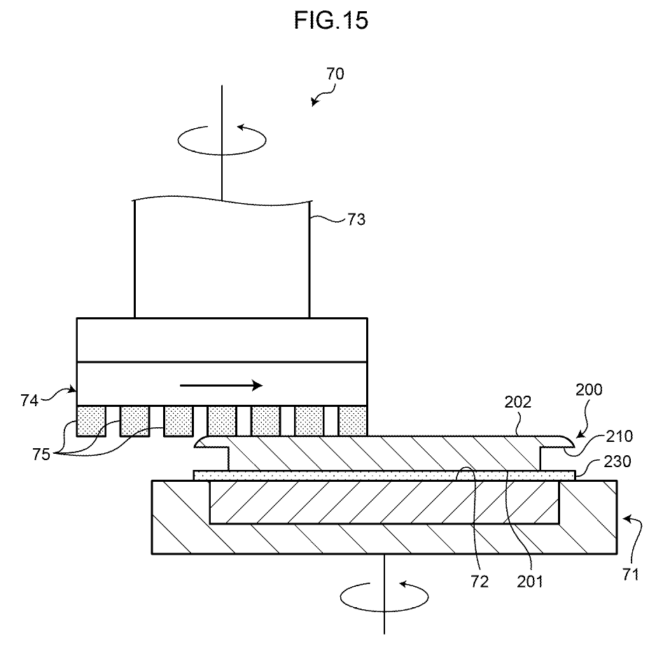

FIG. 15 is a side view schematically illustrating, in a partial cross section, the grinding step of the method for manufacturing a device chip illustrated in FIG. 4. The grinding step 1005 is a step of grinding the back surface 202 of the plate-shaped object 200.

In the first embodiment, at the grinding step 1005, a surface protection tape 230 is attached to the front surface 201 of the plate-shaped object 200, and a grinding apparatus 70 illustrated in FIG. 15 sucks and holds the front surface 201 side of the plate-shaped object 200 on a holding surface 72 of a holding table 71 via the surface protection tape 230. In the first embodiment, at the grinding step 1005, as illustrated in FIG. 15, the grinding apparatus 70 supplies grinding water while rotating a grinding wheel 74 about the axis with a spindle 73 and rotating the holding table 71 about the axis, and causes abrasive segments 75 to come into contact with the back surface 202 of the plate-shaped object 200 and come close to the holding table 71 at a predetermined feed rate. In the first embodiment, at the grinding step 1005, the grinding apparatus 70 grinds the back surface 202 of the plate-shaped object 200 with the abrasive segments 75, thus thins the plate-shaped object 200 to a predetermined thickness, and removes the chamfered portion 205 over the entire circumference.

### Division Step

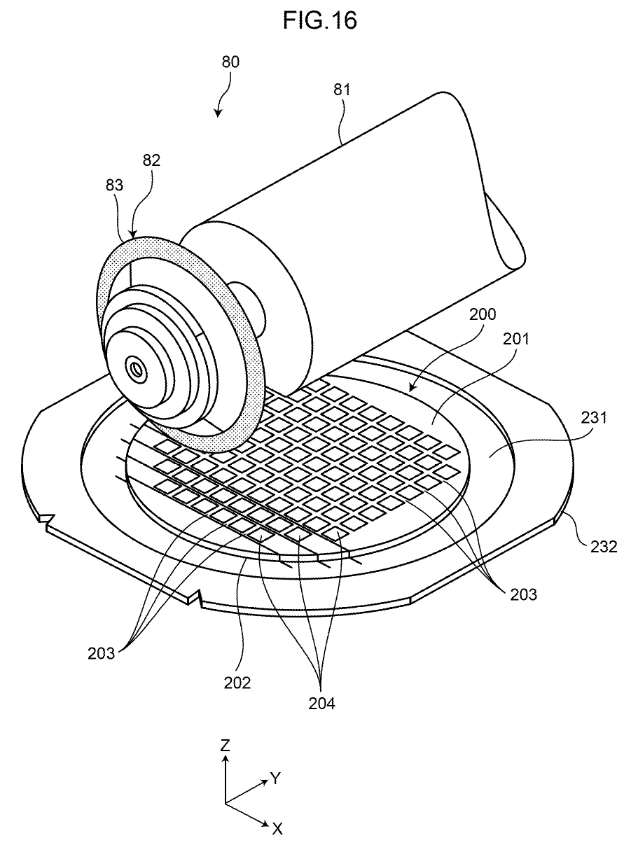

FIG. 16 is a perspective view schematically illustrating the division step of the method for manufacturing a device chip illustrated in FIG. 4. The division step 1006 is a step of dividing the plate-shaped object 200 along the planned division lines 203 to manufacture device chips 220.

In the first embodiment, at the division step 1006, the surface protection tape 230 is removed from the front surface 201 of the plate-shaped object 200, a central portion of a disk-shaped tape 231 having a larger diameter than the plate-shaped object 200 is attached to the back surface 202 of the plate-shaped object 200, a ring-shaped frame 232 is attached to an outer edge portion of the tape 231, and the plate-shaped object 200 is supported by the frame 232. In the first embodiment, at the division step 1006, a cutting apparatus 80 illustrated in FIG. 16 holds the plate-shaped object 200 on a not-illustrated holding table, and clamps the frame 232 with a not-illustrated clamp unit.

In the first embodiment, at the division step 1006, the cutting apparatus 80 images the plate-shaped object 200 with a not-illustrated imaging unit, and executes alignment of aligning a cutting blade 82 of a cutting unit 81 and the planned division line 203 of the plate-shaped object 200. In the first embodiment, at the division step 1006, as illustrated in FIG. 16, the cutting apparatus 80, while relatively moving the cutting blade 82 and the plate-shaped object 200 along the planned division line 203, causes a cutting edge 83 of the cutting blade 82 to cut into the planned division line 203 of the plate-shaped object 200 until the cutting edge 83 of the cutting blade 82 reaches the tape 231, and cuts the planned division line 203. In the first embodiment, in the division step 1006, as illustrated in FIG. 16, the cutting apparatus 80 cuts all the planned division lines 203 with the cutting blade 82 to divide the plate-shaped object 200 into individual device chips 220.

When the position of the lower end of the cutting edge of the cutting blade 21 is detected with a non-contact sensor and the chamfered portion 205 of the outer edge 206 of the plate-shaped object 200 is cut, errors occur in the depth, etc. of the removed part 210 of the disk portion 209 and the chamfered portion 205 because the cutting blade 21 is in an unloaded state when the position of the lower end of the cutting edge of the cutting blade 21 is being detected with the non-contact sensor, and a load is applied to the cutting blade 21 when the chamfered portion 205 of the outer edge 206 of the plate-shaped object 200 is being cut.

Thus, as described above, the method for manufacturing a device chip and the processing apparatus 1 according to the first embodiment perform cutting by causing the cutting edge of the cutting blade 21 to cut in by a distance 207-2 smaller than a predetermined distance 207 and by a depth 208-2 shallower than a predetermined depth 208 at the preliminary processing step 1002 and correct the position of the cutting blade 21 based on the measurement result at the measurement step 1003 to perform cutting at the main processing step 1004.

As a result, the method for manufacturing a device chip and the processing apparatus 1 according to the first embodiment provide an advantage effect of being able to remove the part 210 of the disk portion 209 and the chamfered portion 205 by a target predetermined distance 207 from the outer edge 206 and by a target predetermined depth 208 from the front surface 201.

In the case where, at the preliminary processing step 1002, cutting is performed by causing the cutting edge of the cutting blade 21 to cut in by a distance 207-2 smaller than a predetermined distance 207 and by a predetermined depth 208, only the portion of the cutting edge of the cutting blade 21 used at the preliminary processing step 1002 performs cutting, and the cutting edge of the cutting blade 21 may be unevenly abraded.

In contrast, the method for manufacturing a device chip and the processing apparatus 1 according to the first embodiment perform cutting by causing the cutting edge of the cutting blade 21 to cut in by a distance 207-2 smaller than a predetermined distance 207 and by a depth 208-2 shallower than a predetermined depth 208 in the preliminary processing step 1002 and correct the position of the cutting blade 21 based on the measurement result of the measurement step 1003 to perform cutting at the main processing step 1004. Thus, the method for manufacturing a device chip and the processing apparatus 1 according to the first embodiment provide an advantage effect of being able to suppress uneven abrasion of the cutting edge of the cutting blade 21.

### First Modification Example

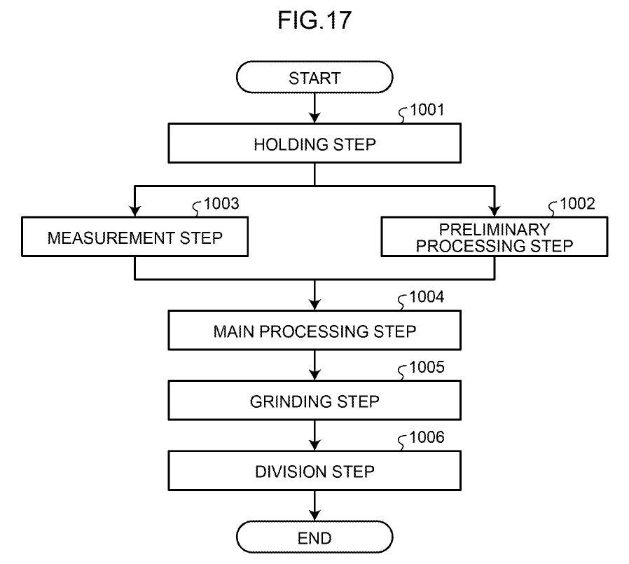

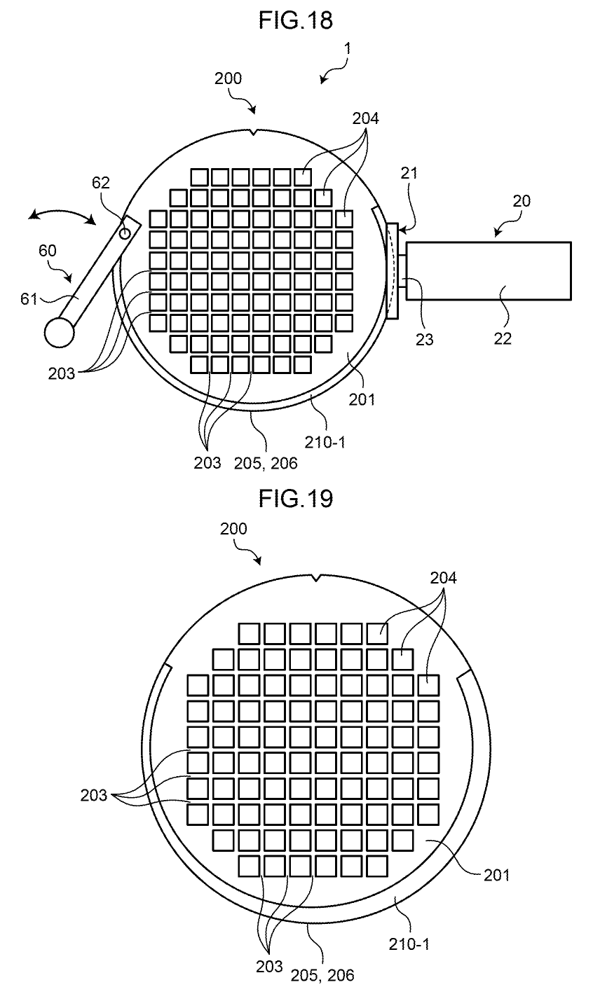

Next, a method for manufacturing a device chip according to a first modification example of the first embodiment is described. FIG. 17 is a flowchart illustrating a flow of a method for manufacturing a device chip according to the first modification example of the first embodiment. FIG. 18 is a plan view schematically illustrating a preliminary processing step and a measurement step of the method for manufacturing a device chip illustrated in FIG. 17. FIG. 19 is a plan view schematically illustrating another example of a plate-shaped object after the preliminary processing step of the method for manufacturing a device chip illustrated in FIG. 17. In FIGS. 17, 18, and 19, the same portions as in the first embodiment are denoted by the same reference numerals, and a description is omitted.

In the first modification example, as illustrated in FIG. 17, the method for manufacturing a device chip performs a preliminary processing step 1002 and a measurement step 1003 simultaneously, and then performs a main processing step 1004. In the first modification example, at the preliminary processing step 1002 and the measurement step 1003, in the processing apparatus 1, as illustrated in FIG. 18, the processing control unit 101 of the controller 100 causes the cutting edge of the cutting blade 21 to cut into the plate-shaped object 200 by a preliminary processing distance 207-1 and by a preliminary processing depth 208-1, and rotates the chuck table 10 about the rotation axis 12; when the region processed at the preliminary processing step 1002 of the plate-shaped object 200 is located under the measurement element 62 of the measurement unit 60, the distance 207-2 and the depth 208-2 described above are measured.

The method for manufacturing a device chip and the processing apparatus 1 according to the first modification example perform cutting by causing the cutting edge of the cutting blade 21 to cut in by a distance 207-2 smaller than a predetermined distance 207 and by a depth 208-2 shallower than a predetermined depth 208 at the preliminary processing step 1002 and correct the position of the cutting blade 21 based on the measurement result of the measurement step 1003 to perform cutting at the main processing step 1004. Thus, as in the first embodiment, the method for manufacturing a device chip and the processing apparatus 1 according to the first modification example provide an advantage effect of being able to remove the chamfered portion 205 by a target predetermined distance 207 from the outer edge 206 and by a target predetermined depth 208 from the front surface 201.

Further, the method for manufacturing a device chip and the processing apparatus 1 according to the first modification example perform the preliminary processing step 1002 and the measurement step 1003 simultaneously, and thus provide an advantage effect of being able to shorten the time required for processing.

In the first modification example, at the preliminary processing step 1002, the processing control unit 101 of the controller 100 may cause the cutting edge of the cutting blade 21 to cut into the plate-shaped object 200 by a preliminary processing distance 207-1 and by a preliminary processing depth 208-1, and while rotating the chuck table 10 about the rotation axis 12, control the Y-axis movement unit 42 to move the cutting edge of the cutting blade 21 toward the center of the plate-shaped object 200 and control the Z-axis movement unit 43 to lower the cutting edge of the cutting blade 21. Thus, in the first modification example, at the preliminary processing step 1002, as illustrated in FIG. 19, the distance 207-2 may be made to be gradually larger (longer), and the depth 208-2 may be made to be gradually deeper.

In this manner, in the first modification example, at the preliminary processing step 1002, both performing processing while changing the processing position from a processing position smaller than the predetermined distance 207 toward the predetermined distance 207 and performing processing while changing the processing depth from a processing position shallower than the predetermined depth 208 toward the predetermined depth 208 may be performed.

In the present invention, at the preliminary processing step 1002, at least one of performing processing while changing the processing position from a processing position smaller than the predetermined distance 207 toward the predetermined distance 207 or performing processing while changing the processing depth from a processing position shallower than the predetermined depth 208 toward the predetermined depth 208 may be performed.

In the present invention, in the preliminary processing step 1002, while rotating the chuck table 10 around the rotation axis 12, the Y-axis movement unit 42 may be controlled to move the cutting edge of the cutting blade 21 toward the center of the plate-shaped object 200 and the Z-axis movement unit 43 may be controlled to lower the cutting edge of the cutting blade 21, and during the preliminary processing step 1002 the correction calculation unit 104 of the controller 100 may calculate the difference described above that is the amount of correction; after the distance 207-2 and the depth 208-2 become the predetermined distance 207 and the predetermined depth 208 after correction, the preliminary processing step 1002 to the main processing step 1004 may be continuously performed.

In these cases, the volume of the region processed at the main processing step 1004 can be suppressed as compared to the first embodiment, and thus an advantage effect of being able to shorten the time required for processing more is provided.

### Second Modification Example

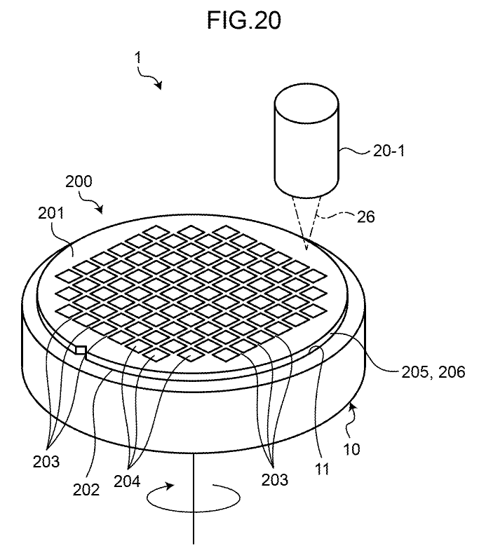

Next, a processing apparatus 1 of a method for manufacturing a device chip according to a second modification example of the first embodiment is described. FIG. 20 is a perspective view schematically illustrating a preliminary processing step and a main processing step of a method for manufacturing a device chip according to the second modification example of the first embodiment. In FIG. 20, the same portions as in the first embodiment are denoted by the same reference numerals, and a description is omitted.

In the second modification example, as illustrated in FIG. 20, the processing apparatus 1 includes a laser light irradiation unit 20-1 that is a processing unit, and at the preliminary processing step 1002 and the main processing step 1004, processes the chamfered portion 205 by irradiating the plate-shaped object 200 with laser light 26 having transmissivity or absorbability from the laser light irradiation unit 20-1.

The method for manufacturing a device chip and the processing apparatus 1 according to the second modification example process the plate-shaped object 200 by a distance 207-2 smaller than a predetermined distance 207 and by a depth 208-2 shallower than a predetermined depth 208 at the preliminary processing step 1002 and correct the predetermined distance 207 and the predetermined depth 208 based on the measurement result of the measurement step 1003 to perform processing at the main processing step 1004. Thus, as in the first embodiment, the method for manufacturing a device chip and the processing apparatus 1 according to the second modification example provide an advantage effect of being able to remove the chamfered portion 205 by a target predetermined distance 207 from the outer edge 206 and by a target predetermined depth 208 from the front surface 201.

In the second modification example, as in the first modification example, the preliminary processing step 1002 and the measurement step 1003 may be performed simultaneously, and at the preliminary processing step 1002, at least one of performing processing while changing the processing position from a processing position smaller than the predetermined distance 207 toward the predetermined distance 207 or performing processing while changing the processing depth from a processing position shallower than the predetermined depth 208 toward the predetermined depth 208 may be performed.

The present invention is not limited to the above embodiments. That is, various modifications can be made without departing from the gist of the present invention. For example, in the present invention, the division step 1006 is not limited to dividing the plate-shaped object 200 into device chips 220 by performing cutting with the cutting blade 21. In the present invention, at the division step 1006, the plate-shaped object 200 may be divided into device chips 220 by being irradiated with a laser beam of a wavelength having absorbability, or the plate-shaped object 200 may be irradiated with a laser beam of a wavelength having transmissivity to form a modified layer along the planned division lines 203, and then be divided into device chips 220 starting from the modified layer.

Further, although in the first embodiment the preliminary processing step 1002 uses the processing unit to perform both processing the chamfered portion 205 by a distance smaller than the predetermined distance 207 and processing the chamfered portion 205 by a distance shallower than the predetermined depth, in the present invention the preliminary processing step 1002 needs only to use the processing unit to perform at least one of processing the chamfered portion 205 by a distance smaller than the predetermined distance 207 or processing the chamfered portion 205 by a distance shallower than the predetermined depth.

Further, although in the first embodiment the main processing step 1004 uses the processing unit to perform both cutting the plate-shaped object 200 by the predetermined distance 207 and cutting the plate-shaped object 200 by the predetermined depth 208, in the present invention the main processing step 1004 needs only to use the processing unit to perform at least one of cutting the plate-shaped object 200 by the predetermined distance 207 or cutting the plate-shaped object 200 by the predetermined depth 208.

Further, in the present invention, a plate-shaped object 200 formed by bonding two wafers together may be processed. Further, in the present invention, at the preliminary processing step 1002, the entire circumference of the plate-shaped object 200 may be processed, or a part in the circumferential direction of the plate-shaped object 200 may be processed.

The present invention provides the advantage effect of being able to remove a chamfered portion by a target distance from the outer peripheral edge and by a target depth.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A method for processing a plate-shaped object having a chamfered portion formed at an outer peripheral edge thereof, in which a predetermined distance from the outer peripheral edge in a radial direction of the plate-shaped object and a predetermined depth from a front surface of the plate-shaped object are processed to remove at least a part of the chamfered portion,
the method comprising:
a preliminary processing step including
rotating a chuck table that holds the plate-shaped object on a holding surface thereof about a rotation axis intersecting the holding surface, and
performing, using a processing unit, at least one of processing the chamfered portion by a distance smaller than the predetermined distance or processing the chamfered portion by a depth shallower than the predetermined depth;
a measurement step including measuring at least one of a distance from the outer peripheral edge or a depth from the front surface of a region processed at the preliminary processing step; and
a main processing step including
rotating the chuck table that holds the plate-shaped object on the holding surface thereof by at least 360 degrees about the rotation axis intersecting the holding surface, and
performing, using the processing unit, at least one of processing the plate-shaped object up to the predetermined distance or processing the plate-shaped object up to the predetermined depth, based on at least one of the distance or the depth measured at the measurement step.

2. The method for processing a plate-shaped object according to claim 1, wherein the main processing step is performed after the preliminary processing step and the measurement step are performed simultaneously.

3. The method for processing a plate-shaped object according to claim 2, wherein
the preliminary processing step includes performing at least one of:
performing processing while changing a processing position from a processing position smaller than the predetermined distance toward the predetermined distance; or performing processing while changing a processing depth from a processing position shallower than the predetermined depth toward the predetermined depth.

4. The method for processing a plate-shaped object according to claim 1, wherein each of the preliminary processing step and the main processing step includes processing the chamfered portion with a cutting blade attached to a distal end of a spindle.

5. The method for processing a plate-shaped object according to claim 1, wherein
each of the preliminary processing step and the main processing step includes processing the chamfered portion by irradiating the outer peripheral edge of the plate-shaped object with laser light having transmissivity or absorbability.

6. A method for manufacturing a semiconductor device chip, the method comprising:
a preliminary processing step including
rotating a chuck table that holds a plate-shaped object on a holding surface thereof about a rotation axis intersecting the holding surface, the plate-shaped object having semiconductor devices respectively formed in regions on a front surface partitioned by a plurality of intersecting division planned lines and a chamfered portion formed at an outer peripheral edge thereof, and
performing, using a processing unit, at least one of processing the chamfered portion by a distance smaller than a predetermined distance or processing the chamfered portion by a depth shallower than a predetermined depth;
a measurement step including measuring at least one of a distance from the outer peripheral edge or a depth from the front surface of a region processed at the preliminary processing step;
a main processing step including
rotating the chuck table that holds the plate-shaped object on the holding surface thereof by at least 360 degrees about the rotation axis intersecting the holding surface, and
performing, using the processing unit, at least one of processing the plate-shaped object up to the predetermined distance or processing the plate-shaped object up to the predetermined depth, based on at least one of the distance or the depth measured at the measurement step;
a grinding step including grinding a back surface of the plate-shaped object; and
a division step including dividing the plate-shaped object along the planned division lines to manufacture semiconductor device chips.

7. A processing apparatus comprising:
a chuck table having a rotation axis intersecting a holding surface thereof;
a processing unit that processes a plate-shaped object held on the chuck table;
a measurement unit that measures a region processed by the processing unit; and
a controller, wherein
the controller is configured to include:
a processing region setting unit that sets a target processing region;
a preliminary processing region setting unit that sets a preliminary processing region smaller than the target processing region;
a correction calculation unit that calculates an amount of correction based on a region measured by the measurement unit and the preliminary processing region; and
a correction command unit that corrects a processing position of the processing unit based on the amount of correction calculated by the correction calculation unit.

8. The processing apparatus according to claim 7, wherein
the target processing region includes a predetermined distance in a direction parallel to the holding surface.

9. The processing apparatus according to claim 7, wherein
the target processing region includes a predetermined
depth in a direction intersecting the holding surface.
